(19) United States
(12) Patent Application Publication
(10) Pub. No.: US 2010/0326357 A1
(43) Pub. Date: Dec. 30, 2010

(54) NOZZLE AND FURNACE HAVING THE SAME

(76) Inventors: Wei-Hung Huang, Hsinchu City (TW); Po-Yueh Liu, Hsinchu City (TW); Hsing-Hung Lin, Taipei City (TW); Yi-Deng Huang, Yilan County (TW); Chi-Fu Chen, Taichung City (TW)

Correspondence Address: NORTH AMERICA INTELLECTUAL PROPERTY CORPORATION, P.O. BOX 506, MERRIFIELD, VA, 22116, US

(21) Appl. No.: 12/494,292

(22) Filed: Jun. 30, 2009

(51) Int. Cl. C23C 16/54

(52) U.S. Cl. 118/724; 118/715

(57) ABSTRACT

A nozzle and a furnace having the same are provided. The furnace has a high vacuum fitting used to assemble the nozzle to the furnace. The nozzle includes a first tube part and a second tube part connecting to the first tube part. In addition, an immobilization device is disposed on a surface of the first tube part. The immobilization device is corresponding to an o-ring of the high vacuum fitting and sheathed by the o-ring to steadily immobilize the nozzle to the furnace.

### BACKGROUND OF THE INVENTION

1. Field of the Invention

The present invention is related to a nozzle, and particularly, to a nozzle having an immobilization device on a surface thereof.

2. Description of the Prior Art

Chemical vapor deposition (CVD) process is a popular method used for depositing a polysilicon layer in current semiconductor technology. Please refer to FIG. 1, which is a schematic diagram illustrating a conventional vertical type furnace 10. The vertical type furnace 10 includes an inner tube 12, an outer tube 14, a boat 16, and a nozzle 18 disposed between the inner tube 12 and the boat 16. The inner tube 12 and the outer tube 14 are disposed concentrically with each other with a predetermined gap. The outer tube 14 is surrounded by a heating cover 19, which includes a heater 15 and a thermal insulator 17. The nozzle 18 is a tube having a smooth surface and an end of the nozzle is connected to a gas supply system 20. The nozzle 18 is assembled on a sidewall of a housing 24 of the furnace 10 by a high vacuum fitting 22. The high vacuum fitting 22 has a first ferrule 221, a second ferrule 222, and a third ferrule 223 to hold the nozzle 18. An o-ring 224 is disposed between the first ferrule 221 and the second ferrule 222 to enhance the airtightness among the first ferrule 221, the second ferrule 222, and the nozzle 18.

Chemical reactions are occurred during the CVD process to form a thin film. During the CVD process, the atmospheric pressure in the furnace 10 is maintained in a low pressure or in vacuum. The variation of the atmospheric pressure may result in displacement of the nozzle 18, in which the nozzle is rotated along the axis of a portion of the nozzle 18 holding by the high vacuum fitting 22 and another portion of the nozzle 18 disposed between inner tube 12 and the boat 16 is leaned against an inner wall of the inner tube 12. Therefore, the direction of the gas ejected from the nozzle 18 is never parallel to the wafers disposed on the boat 16 and the thin film formed on the wafers is formed without uniformity. As a result, the wafers with uneven thin film are scraped. Besides, the product of the CVD process is not only depositing on the wafers of the boat 16, but also depositing on the inner wall of the inner tube 16 and the surface of the nozzle 18. The inner tube 12, the nozzle 18, and the accumulated deposit have distinct thermal expansion coefficients that lead to a breakage of the nozzle 18 where contacts the inner wall of the inner tube 12 during the thermal process. Therefore, the loss of the process and the process cost are increased.

### SUMMARY OF THE INVENTION

In order to overcome the problems, the present invention provides a nozzle having an immobilization device thereon to prevent displacement of the nozzle and the attachment between the nozzle and the inner wall of the furnace.

According to the claimed invention, a nozzle is provided. The nozzle is disposed in a furnace and has a first tube part and a second tube part connecting to the first tube part. In addition, the first tube part has an immobilization device disposed on a surface thereof.

Additionally, the claimed invention further discloses a furnace. The furnace includes an inner tube, an outer tube, a housing, a nozzle, and a high vacuum fitting. The outer tube is disposed surrounding the inner tube. The housing is disposed under the inner tube and the outer tube. The housing, the inner tube, and the outer tube define a chamber. In addition, the nozzle has an immobilization device disposed on a surface thereof. The high vacuum fitting is used to assemble the nozzle to the housing. The high vacuum fitting has at least an o-ring, which sheathes the immobilization device of the nozzle.

The nozzle of the present invention has the immobilization device disposed on the surface thereof. The immobilization device is tightly sheathed by the o-ring of the high vacuum fitting to firmly immobilize the nozzle to the furnace. Therefore, the displacement of the nozzle resulting from variation of the atmospheric press may be prevented.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a conventional vertical type furnace.

FIGS. 2-5 are schematic diagrams illustrating a nozzle and a furnace having the nozzle according to a preferred embodiment of the present invention.

FIG. 6 is a schematic diagram illustrating another nozzle and an o-ring corresponding to the nozzle according to another preferred embodiment of the present invention.

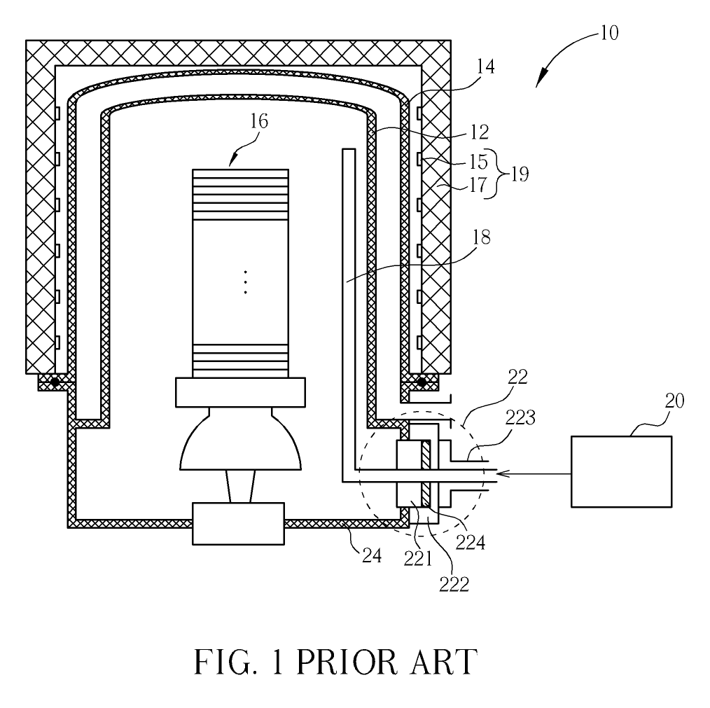

### DETAILED DESCRIPTION

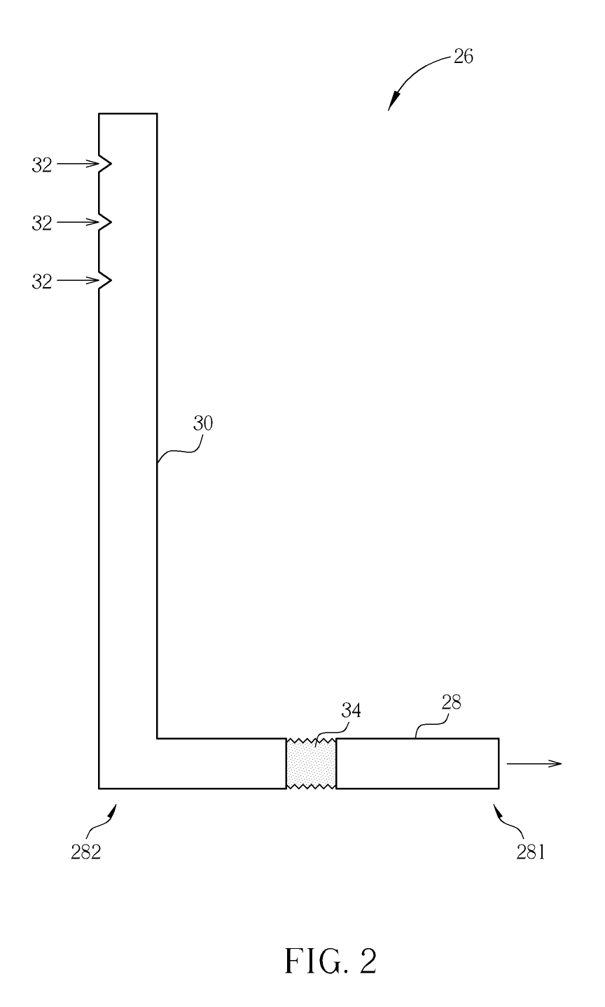

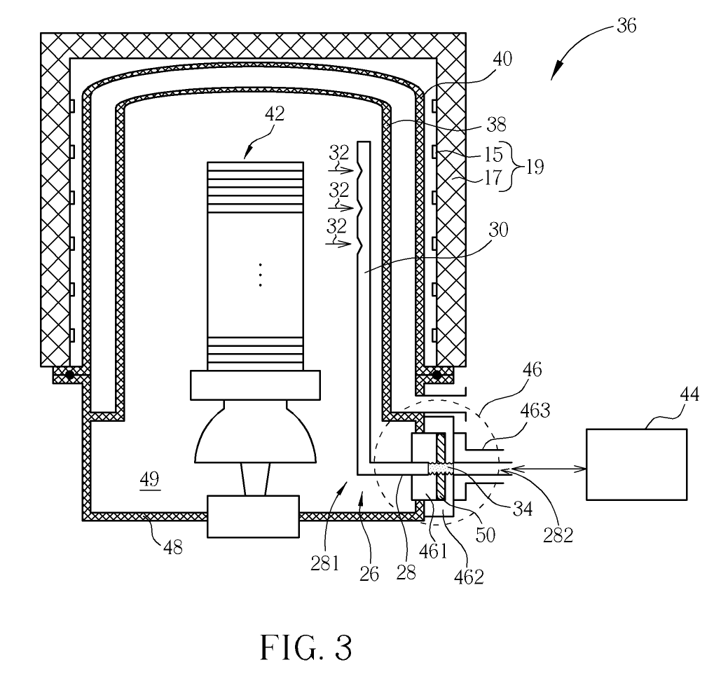

Please refer to FIGS. 2-5. FIGS. 2-5 are schematic diagrams illustrating a nozzle 26 and a furnace 36 having the nozzle 26 according to a preferred embodiment of the present invention. Please refer to FIG. 2. The nozzle 26 is a tube, and preferably an L-shaped tube made of cylindrical quarts body. The nozzle 26 includes a first tube part 28 and a second tube part 30. The first tube part 28 has a first terminal 281 connecting to a gas supply system 42 (shown in FIG. 3) and a second terminal 282 disposed opposite to the first terminal 281. The second terminal 282 of the first tube part 28 is connected to the second tube part 30. The second tube part 30 has a plurality of exhaust ports 38, which allow the gas entering from the first terminal 281 of the nozzle 26 to eject and join the chemical reaction that forms a product disposed on a predetermined wafer. The nozzle 26 of the present embodiment is an L-shaped tube and the first tube part 28 is disposed perpendicularly to the second tube part 30. The nozzle 26 may be a non-linear tube and so that the included angle between the first tube part 28 and the second tube part 30 is not equal to 180°. The included angle between the first tube part 28 and the second tube part 30 may be modified depending on the furnace. It should be noted that the nozzle 26 has an immobilization device 34 disposed on a surface of the first tube part 28 between the first terminal 281 and the second terminal 282. The immobilization device 34 may be a rough surface (shown in FIG. 2), formed by a chemical process, such as an etch process; or a physical method, such as a grinding process or a sandblasting process, to process the surface of the first tube part 28. The smooth surface of the first tube part 28 is processed to form a rough surface having a roughness average less than 5 micrometers, and preferably a roughness of 1-3 micrometers.

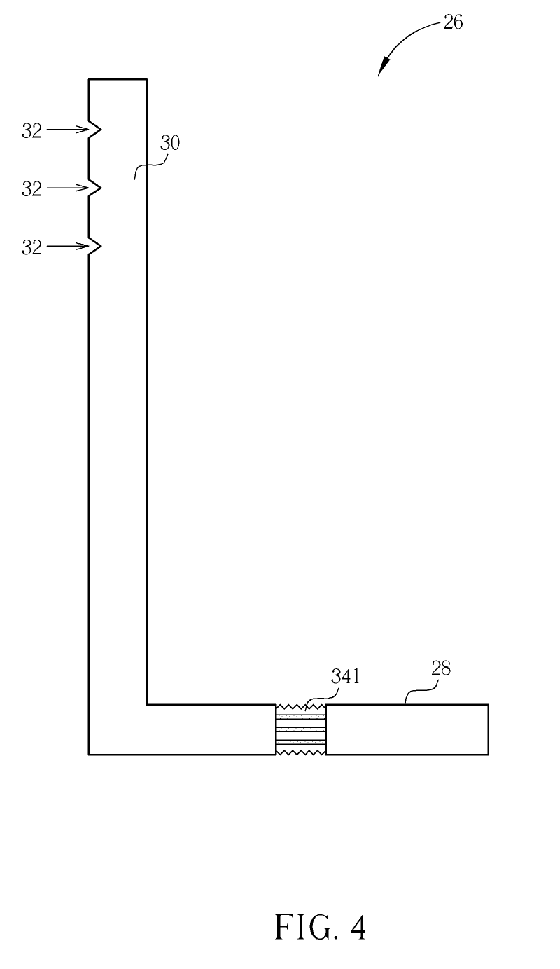

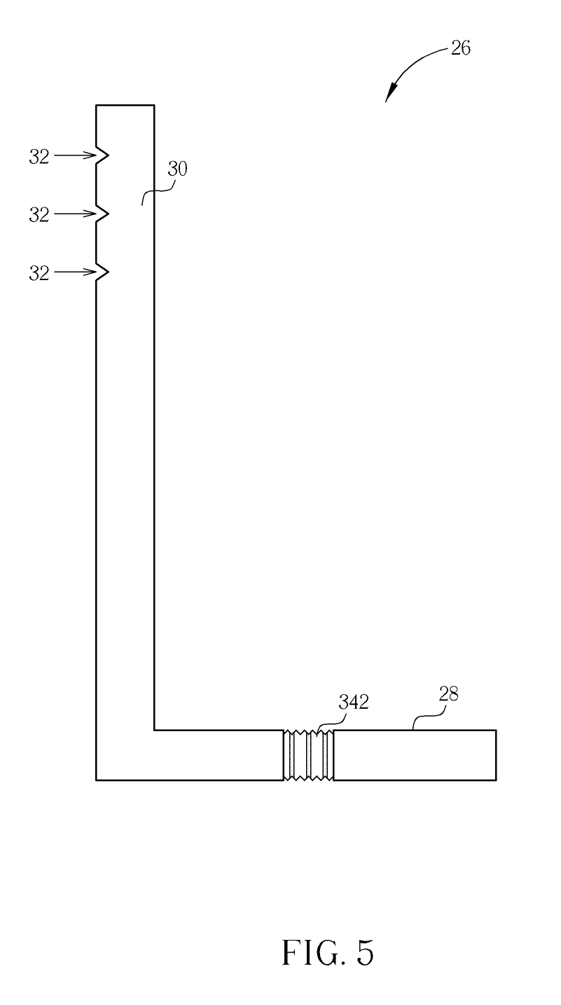

Please refer to FIG. 3, which is a schematic diagram illustrating the furnace 36 having the nozzle 26 of the present invention. The furnace 36 includes a nozzle 26, an inner tube 38, an outer tube 40, a boat 42, a gas supply system 44, and a housing 48. Similar to the conventional vertical type furnace, the furnace 36 has the heating cover 19, which includes a heater 15 and a thermal insulator 17. A chamber 49 for CVD process is defined by the inner tube 38, the outer tube 40, and the housing 48. The nozzle 26 is fixed by virtue of a high vacuum fitting 46 sheathing the first tube part 28 of the nozzle 26, so that the nozzle 26 is immobilized to a housing 48. The second tube part 30 of the nozzle 26 is disposed in the gap between the inner tube 38 and the boat 42 in the chamber 49. The high vacuum fitting 46 has a first ferrule 461, a second ferrule 462, and a third ferrule 463 serially holding the nozzle 26 from the second terminal 282 to the first terminal 281 of the first tube part 28. An o-ring 50 is disposed between the first ferrule 461 and the second ferrule 462. The o-ring 50 surrounds the immobilization device 34 and tightly sheathes the immobilization device 34. The immobilization device 34 of the present invention is a rough surface and so that the friction between the immobilization device 34 and the o-ring 50 is increased to firmly fixed the nozzle 26 in the high vacuum fitting 46. In addition, the friction between the immobilization device 34 and the o-ring 50 prevents the second tube part 30 from being in touch with the inner wall of the furnace 36 and therefore prevents the displacement of the nozzle 26. The immobilization device 34 of the afore-mentioned embodiment is processed upon a portion of the surface of the first tube part 26 to form a section of rough surface on the first tube 26. Moreover, the immobilization device 34 may be a patterned rough surface 341 having striated lines parallel to the first tube part 26 (shown in FIG. 4) or a patterned rough surface 342 having striated lines perpendicular to the first tube part 26 (shown in FIG. 5).

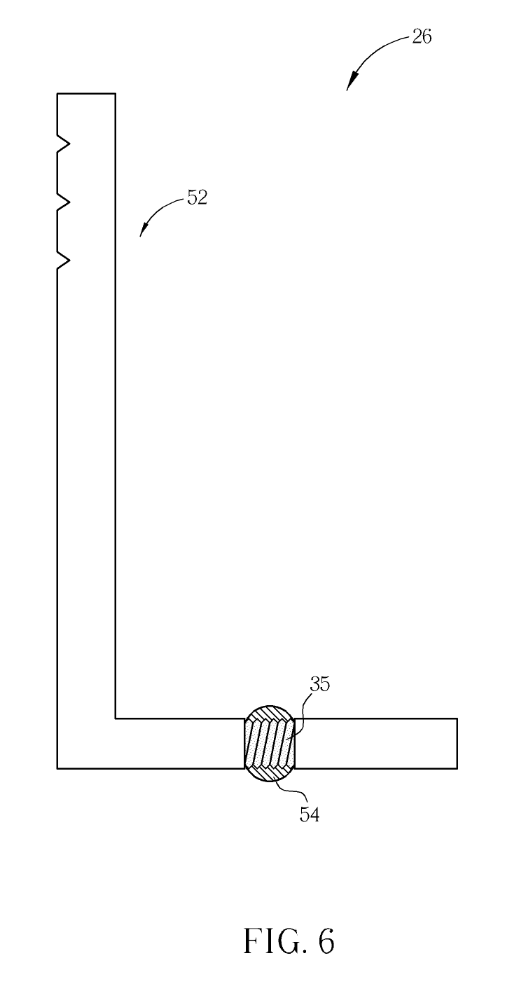

Please refer to FIG. 6, which is a schematic diagram illustrating another nozzle 52 and an o-ring 54 corresponding to the nozzle according to another preferred embodiment of the present invention. The nozzle 52 is fixed to the furnace 36 shown in the previous embodiment. In contrary to the previous embodiment, the immobilization device 35 of the nozzle 52 has a threading surface. Since the o-ring 54 sheathing the immobilization device 35 is made of elastic polymer, the assembly of the nozzle 52 and the o-ring 54 results in forming another the threading surface on a inner wall of the o-ring 54 corresponding to the threading surface of the immobilization device 35. Therefore, the o-ring 54 and the immobilization device 35 are threadably mate and firmly assembled with each other. Different thread options may be used for the o-ring 54 and the immobilization device 35. It should be noted that the nozzle of the present invention may have a plurality of immobilization devices on it surface. These immobilization devices may be sheathed by one o-ring of a respective width or may be sheathed with a plurality of o-rings. In addition, the strength between the o-ring and the immobilization device may therefore be enhanced to prevent the rotation and the displacement of the nozzle.

As described above, the nozzle of the present invention has the immobilization device disposed on a surface thereof. The immobilization device may be a rough surface or a threading surface to increase the contact surface and the friction between the immobilization device and the o-ring that prevents rotation of the nozzle. In addition, the immobilization device may further prevent the nozzle from contacting the inner wall of the furnace and prevent the breakage of the nozzle caused by variations of thermal expansion coefficient of the nozzle and the furnace. Furthermore, the nozzle of the present invention is processed by a respective machine. Comparing to the processes for forming nozzle with specific structures, the processes for forming the nozzle of the present invention is much simplified. The nozzle of the present invention may have more than one immobilization device. The nozzle of the present invention may have both of the rough surface and threading surface on the surface thereof.

Those skilled in the art will readily observe that numerous modifications and alterations of the device and method may be made while retaining the teachings of the invention.

What is claimed is:

1. A nozzle disposed in a furnace, comprising:
a first tube part comprising an immobilization device on a surface thereof; and
a second tube part connecting to the first tube part.

2. The nozzle of claim 1, wherein the immobilization device comprises a rough surface.

3. The nozzle of claim 2, wherein the rough surface has a roughness average less than 5 micrometers.

4. The nozzle of claim 3, wherein the rough surface has a roughness average of 1-3 micrometers.

5. The nozzle of claim 1, wherein the immobilization device comprises a patterned rough surface.

6. The nozzle of claim 1, wherein furnace comprises a high vacuum fitting to sheathe the nozzle and to assemble the nozzle to the furnace.

7. The nozzle of claim 6, wherein the high vacuum fitting comprises at least an o-ring sheathing the immobilization device of the nozzle.

8. The nozzle of claim 6, wherein the immobilization device comprises a threading surface.

9. The nozzle of claim 1, wherein the first tube part is disposed perpendicularly to the second tube part.

10. The nozzle of claim 1, wherein the nozzle comprises a non-liner tube.

11. The nozzle of claim 10, wherein the included angle between the first tube part and the second tube part is not equal to 180°.

12. A furnace, comprising:
an inner tube;
an outer tube disposed surrounding the inner tube;
a housing disposed under the inner tube and the outer tube, the housing, the inner tube, and the outer tube defining a chamber;
a nozzle comprising an immobilization device disposed on a surface thereof; and
a high vacuum fitting assembling the nozzle to the housing, the high vacuum fitting comprising at least an o-ring surrounding and contacting the immobilization device of the nozzle.

13. The furnace of claim 12, wherein the nozzle comprises a non-liner tube.

14. The furnace of claim 13, wherein the nozzle comprising:
a first tube part having the immobilization device on a surface thereof; and
a second tube part connecting to the first tube part, the included angle between the first tube part and the second tube part is not equal to 180°.

15. The furnace of claim 14, wherein the first tube part is disposed perpendicularly to the second tube part.

16. The furnace of claim 12, wherein the immobilization device comprises rough surface.

17. The furnace of claim 12, wherein the rough surface has a roughness average less than 5 micrometers.

18. The furnace of claim 12, wherein the rough surface has a roughness average of 1-3 micrometers.

19. The furnace of claim 12, wherein the immobilization device comprises a threading surface.

20. The furnace of claim 12, wherein the immobilization device comprises a patterned rough surface.
